(19) United States
(12) Patent Application Publication
(10) Pub. No.: US 2025/0194163 A1
(43) Pub. Date: Jun. 12, 2025

(54) STACKED FET WITH SHIFTED CHANNEL STRUCTURE

(71) Applicant: International Business Machines Corporation, Armonk, NY (US)

(72) Inventors: Shay Reboh, Guilderland, NY (US); Albert M. Chu, Nashua, NH (US); Junli Wang, Slingerlands, NY (US); Brent A. Anderson, Jericho, VT (US)

(21) Appl. No.: 18/535,332

(22) Filed: Dec. 11, 2023

(51) Int. Cl. H01L 29/786; H01L 27/088; H01L 29/06; H01L 29/423; H01L 29/775

(52) U.S. Cl. CPC H10D 30/6757; H10D 30/43; H10D 30/6735; H10D 84/834; H10D 62/121

(57) ABSTRACT

A semiconductor device includes a stacked transistor structure including a column having field effect transistors on two levels in the column, the two levels including a top tier and bottom tier. First channels of a field effect transistor are disposed on a first side of the column at the top tier and second channels of a second field effect transistor disposed on a second side of the column opposite the first side at the bottom tier to form an offset between the first channels and the second channels within the column.

### BACKGROUND

The present invention generally relates to semiconductor devices and processing methods, and more particularly to semiconductor devices having stacked field effect transistor (FET) structures with components shifted to permit easier access for opposite side contacts and to permit improvements in size scaling.

Areal density is always of concern in semiconductor products. Any opportunity to increase areal density without loss of performance is a sought-after goal. In tri-gate devices, such as forksheet devices, a channel is surrounded by a gate electrode on three sides in cross-section. A fourth side is abutted against a dielectric material such as a gate cut. These devices can be stacked to increase overall device density.

In stacked designs, FETs are stacked across a depth of a chip. These FETs are formed directly over one another in a same column and are aligned within that column. While the alignment of these devices can provide some advantages in manufacturing the device, problems arise when trying to electrically connect to these stacked devices. This is especially the case when attempting to connect from a frontside to a bottom tier FET or the backside to a top tier FET.

Therefore, a need exists to provide access for contacts to easily connect to stacked FET devices. A further need exists for providing a scalable stacked FET configuration that can increase device density.

### SUMMARY

In accordance with an embodiment of the present invention, a semiconductor device includes a stacked transistor structure including a column having field effect transistors on at least two levels in the column, the at least two levels including a top tier and bottom tier. First channels of a field effect transistor are disposed on a first side of the column at the top tier and second channels of a second field effect transistor disposed on a second side of the column opposite the first side at the bottom tier to form an offset between the first channels and the second channels within the column.

In some embodiments, the first channels can abut a dielectric spine of the first side and the second channels about a dielectric spine on the second side. The first channels and the second channels can have different sizes. The first field effect transistor can include a source/drain region offset from a source/drain region of the second field effect transistor within the column. At least one opposite connection contact is disposed within the column and through one of the at least two levels to connect to a source/drain region in the other of the at least two levels. The at least one opposite connection can include two opposite connections within the column. The first field effect transistor can include a tri-gate field effect transistor. The offset can provide overlap between the first channels and the second channels within their respective levels of the at least two levels in the column. The offset can be large enough to prevent overlap between the first channels and the second channels within their respective levels of the at least two levels in the column. The column can be defined in accordance with a cell height and the offset can include a staggered pattern between the first channels and the second channels within their respective levels of the at least two levels in the column. The semiconductor device can further include a dielectric spine aligned through the top tier and bottom tier within the column.

In accordance with another embodiment of the present invention, a semiconductor device includes a stacked transistor structure including a column having tri-gate field effect transistors on at least two levels in the column, the at least two levels including a top tier and bottom tier. A first tri-gate field effect transistor is disposed on a first side of the column at the top tier and a second tri-gate field effect transistor offset from the first tri-gate field effect transistor on a second side of the column opposite the first side at the bottom tier within the column. At least one opposite connection contact is disposed within the column. The at least one opposite connection passes through the column to connect to one of the first and second tri-gate transistors.

In other embodiments, the first tri-gate field effect transistor and the second tri-gate field effect transistor can each include gates with gate conductors that surround three sides of device channels. The gates can be of different sizes. Device channels of the first tri-gate field effect transistor and the second tri-gate field effect transistor can have different sizes. The device channels for the first tri-gate field effect transistor and the second tri-gate field effect transistor can abut dielectric spines on opposite sides of the column. The device channels for adjacent tri-gate field effect transistors in a same layer of the at least two layers can abut a same dielectric spine. The at least one opposite connection can include two opposite connections within the column. The at least one opposite connection can connect to a source drain region of one of the first and second tri-gate transistors.

In accordance with another embodiment of the present invention, a semiconductor device includes a stacked transistor structure including a column having tri-gate field effect transistors on at least two levels in the column, the at least two levels including a top tier and bottom tier. A first tri-gate field effect transistor has channels disposed on a first side of the column at the top tier and a second tri-gate field effect transistor has channels disposed on a second side of the column opposite the first side at the bottom tier to form an offset between the channels of first tri-gate field effect transistor and the channels of the second tri-gate field effect transistor within the column. The offset provides overlap between the channels of the first tri-gate field effect transistor and the channels of the second tri-gate field effect transistor within their respective levels of the at least two levels in the column.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of source or drain regions for a stacked field effect transistor device which are disposed within a column and are offset to permit electrical connection for opposite connection contacts, in accordance with an embodiment of the present invention;

FIG. 2 shows a cross-sectional view of tri-gate transistors for a stacked field effect transistor device with S/D region and contact projections (dotted) which are disposed within a column and are offset with non-overlapping channels and overlapping gates, in accordance with an embodiment of the present invention;

FIG. 3 shows a cross-sectional view of tri-gate transistors for a stacked field effect transistor device with S/D region and contact projections (dotted) which are disposed within a column and are offset with overlapping channels and overlapping gates, in accordance with an embodiment of the present invention;

FIG. 4 shows a cross-sectional view of tri-gate transistors for a stacked field effect transistor device with S/D region and contact projections (dotted) which are disposed within a column and are offset with overlapping gates and channels abutting dielectric spines on opposite sides of the column, in accordance with an embodiment of the present invention;

FIG. 5 shows a cross-sectional view of a tri-gate transistor cell for a stacked field effect transistor device with a cell height of 64 nm and having a single opposite connection contact, in accordance with an embodiment of the present invention;

FIG. 6 shows a cross-sectional view of tri-gate transistors for a stacked field effect transistor device with S/D region and contact projections (dotted) which are disposed within a column and are offset with overlapping channels and overlapping gates and each includes a top gate contact and an opposite connection contact, in accordance with an embodiment of the present invention;

FIG. 7 shows a cross-sectional view of staggered tri-gate transistors for a stacked field effect transistor device with S/D region and contact projections (dotted) which are offset with non-overlapping channels and non-overlapping gates, and each include a top gate contact and an opposite connection contact, in accordance with an embodiment of the present invention;

FIG. 8 shows a cross-sectional view of tri-gate transistor cells for a stacked field effect transistor device which have channels on opposing sides of a cell stack column which abut dielectric spines, in accordance with an embodiment of the present invention;

FIG. 9 shows a cross-sectional view of tri-gate transistors cells for a stacked field effect transistor device which have channels on opposing sides of a cell stack column in an alternating pattern with adjacent device at a same level abutting opposite sides of a same dielectric spine, in accordance with an embodiment of the present invention;

FIG. 10 shows a cross-sectional view of tri-gate transistors cells for a stacked field effect transistor device which have channels on opposing sides of a staggered cell stack, in accordance with an embodiment of the present invention;

FIG. 11 shows a simplified cross-sectional view of a tri-gate transistor with a wafer bonded to provide a second tier, in accordance with an embodiment of the present invention;

FIG. 12 shows a cross-sectional view showing a second tier of devices located relative to a first tier, in accordance with an embodiment of the present invention; and

FIG. 13 shows a cross-sectional view showing first and second tier devices formed and positions relative to a column through the first and second tiers of devices, in accordance with an embodiment of the present invention.

### DETAILED DESCRIPTION

In accordance with embodiments of the present invention, devices and methods are described which include semiconductor devices having stacked transistors. The stacked transistors can include a top tier transistor and a bottom tier transistor although additional transistors can be included in a single stack. The stacked transistors can define a column. The top and bottom transistors are offset, shifted or staggered to permit easier connections from contacts within the column. In particular, channels of the respective top and bottom tier transistors are offset, shifted or staggered. The shifting of position for the channels or the transistor as a whole permits a contact dropped down from an opposite side of the device to easily land on and connect to the transistor on the opposite side. For example, a frontside (top tier) device can be connected by a contact from a backside of the device, and a backside (bottom tier) device can be connected by a contact from a frontside of the device. These opposite side connections will be referred to hereinafter as an “opposite connection” for ease of reference.

It should be understood that top tier and bottom tier are used to provide relative positions. A top tier can be any tier relative to a lower (bottom) tier. In an example, a top tier can be a top side of the device or can be a middle end of the line (MOL) device relative to a front end of the line (FEOL) device. Similarly, a bottom tier can be any tier relative to an upper (top) tier. In an example, a bottom tier can be a back side of the device or can be a middle end of the line (MOL) device relative to a BEOL end of the line (FEOL) device can be a back side of the device or can be a BEOL structure to an MOL structure.

For semiconductor device layouts, cell architecture is defined based on a cell height which is determined on the basis of a number of tracks and pitch of metal lines relative to devices (e.g., transistor widths). Cells are abutted together to implement a given design. Cells with similar height are aligned with each other to attain this similarity among the cells and avoid alignment issues. In useful embodiments, the offset, shifting or staggering of top tier and bottom tier transistors can be employed within a single cell. For example, the top tier transistors have channels or the device itself on one side of the cell while the bottom tier device is on the other side of the cell. In other embodiments, a single cell can include multiple tiers of components (e.g., S/D regions) within the cell. In still other embodiments, top and bottom tiers can have separate cells that can together have aligned cell boundaries or together form a cell with a boundary running from the top to the bottom FET vertically.

In conventional designs where top and bottom tier devices are aligned, to make electrical contact, an additional transverse metal conductor is needed to extend past the top or bottom tier device to provide a landing area for a drop-down contact. This transverse metal conductor adds to the width of the cell or to the chip overall since lateral space is consumed. In some instances, within a cell, for example, stacked transistors need a gap in addition to the lateral space to prevent contact of the additional transverse metal conductor with other contacts and devices. The lateral space plus the gap can be referred to as a distance d. This distance can be different for the top and for the bottom device or component.

The conventional cell with aligned top and bottom transistors would require 2d space to make opposite connections within the cell. In accordance with one embodiment, a shifted top and bottom transistor cell can reduce the 2d space to d space or less.

In one embodiment, cells can be offset or staggered relative to one another to provide room for an opposite connection. For example, a first cell with a top transistor can be misaligned or offset relative to a cell below it with a bottom transistor. The cells of top and bottom FETs being aligned permits an efficient and flexible design in addition to cell scaling. In one embodiment, only the channels are shifted to open space for efficient interconnection. The channels improve an effective width (W_{eff}) and device performance improves as a consequence. The shifted channels permit an efficient layout configuration for backside power distribution networks (BSPDN) with 100% track usage with wider power lines. Shifting channels and/or FETs permits scaling of the cell dimensions resulting in additional design flexibility.

The channel shift to opposing sides of a cell's open space provides for efficient direct/straight source and drain device interconnection for top tier and bottom tier FETs. More specifically, the top tier FET can be connected to the backside with a straight contact. The bottom tier FET can be connected to the front side with a straight contact. Aligned FETs need the contacts to go “around” the top or the bottom FETs to reach the other FET in the column.

In accordance with the present embodiments, stacked transistors can include any type of device. In one embodiment, the transistor types include field effect transistors (FETs). The top device and the bottom device can include different conductivities. N-type FETs (NFETs), P-type FETs (PFETs) can be employed for the top and bottom device, in any combination, e.g., top/bottom can be NFET/PFET (or N/P), P/N, N/N, P/P. In one embodiment, channels of the top or bottom tier device are offset, shifted or staggered relative to each other within a cell or within a portion of the semiconductor device design. The channels refer to the semiconductor channel where conduction is enabled or disabled by the FET device. The channels that are moved to an edge or end portion of the FET device structure can have a dielectric backbone or gate cut abutted against the channels.

In some embodiments, the channels of top and bottom FETs can be partially overlapped over each other in a horizontal direction (e.g., in a plane parallel to a major plane of the semiconductor device). In another embodiment, the channels of the top and bottom tier FETs do not overlap in the horizontal direction. The channels of top and bottom FETs can have different lengths.

In other embodiments, gate structures between top and bottom tier FET gates can be arranged to provide advantages. For example, gate widths for top and bottom tier FET gates can be about the same and can be aligned on an opposite edge, the gate widths can be staggered by a length equal to or lower than the gate width, and the gate widths can be different and aligned or offset. In other embodiments, at least one gate edge of the top tier FET and bottom tier FET is aligned. In other embodiments, gates for the top and bottom FETs can overlap, be staggered or be staggered but have at least one overlapped portion in the horizontal direction. The gates in the different levels of the device can include different sizes or be cut on at least one side to include different dimensions. The gate cuts can include asymmetric lengths or widths.

In other embodiments, shifts and offsets can be implemented between adjacent cells of devices. For example, adjacent bottom tier FETs and/or top tier FETs can have channels, which are shifted closer to one another or even positioned back-to-back, positioned front-to-front or front-to-back.

Embodiments of the present invention can be employed in any type of semiconductor device or chip. For example, the present embodiments can include input/output (IO) circuits, inverters, high performance computing (HPC) circuits, clock buffers, processors, memory devices or any other integrated circuit chip or combinations thereof. Adding additional conductive paths to a device in accordance with embodiments of the present invention can be integrated into any fabrication process with minimal or no impact on expense or processing time. Embodiments of the present invention are particularly useful, with horizontal tri-gate transistors, such as, e.g., forksheet devices. Tri-gate transistors include a gate conductor surrounding three sides of a channel while a fourth side is in contact with a dielectric spine or gate cut.

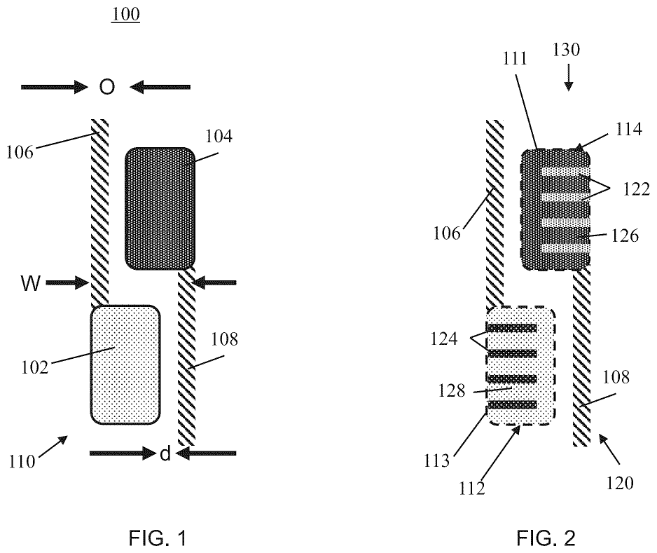

Referring now to the drawings in which like-numerals represent the same or similar elements and initially to FIG. 1, a transistor architecture 100 is shown in accordance with one illustrative embodiment. The architecture 100 includes a cell 110 with source/drain (S/D) regions or epitaxial regions associated with a top tier field effect transistor (FET) source region 104 and a bottom tier FET source region 102. The cell 110 could also include S/D regions or epitaxial regions associated with a top tier FET drain region and a bottom tier FET drain region. The source regions 104 and 102 are offset from one another by a dimension O. Dimension O provides enough width to fit two contacts 106, 108 and sufficient space d for dielectric materials. As mentioned, the dimensions O and d can be different for the top tier versus the bottom tier within the same cell 110.

The cell 110 includes a contact 106 that extends from a front side or top tier of the architecture 100 to make an opposite connection and directly contact the bottom FET source region 102. A contact 108 extends from a backside or bottom tier of the architecture 100 to make an opposite connection and directly contact the top FET source region 104.

Since opposite connections can be made directly by contacts 106, 108 to S/D regions 102 and 104, respectively, an effective cell width does not include lateral extensions for landing the contacts 106, 108. Such lateral extensions would add width to the cell 110.

Referring to FIG. 2, a cell 120 includes tri-gate transistors (e.g., forksheet transistors) 112 and 114 in accordance with another embodiment. A top tier transistor 114 includes a gate 126 and channels 122 that form channels between a source region and a drain region above and below the plane of the page. One of the source/drain regions 111 is depicted as a dotted line around the periphery of the gate 126 to indicate a relative position of a source/drain region. A bottom tier transistor 112 includes a gate 128 and channels 124 that form channels between a source region and a drain region above and below the plane of the page. One of the source/drain regions 113 is depicted as a dotted line around the periphery of the gate 128 to indicate a relative position of a source/drain region. In accordance with one embodiment, the channels 122 of the top tri-gate transistor 114 are located on a first edge and in a first direction right, and the channels 124 of the bottom tri-gate transistor 112 are located on a second edge on an opposite side relative to the first edge and in a second direction opposite the first direction. In one embodiment, the channels 122 and 124 do not overlap with each other when viewed along a direction 130.

The cell 120 includes a contact 106 that extends from a front or top tier to make an opposite connection and directly contact S/D region 113. A contact 108 extends from a backside or bottom tier to make an opposite connection and directly contact S/D region 111. Since opposite connections can be made directly by contacts 106, 108, respectively, an effective cell width does not include lateral extensions for landing the contacts 106, 108. Such lateral extensions would add width to the cell.

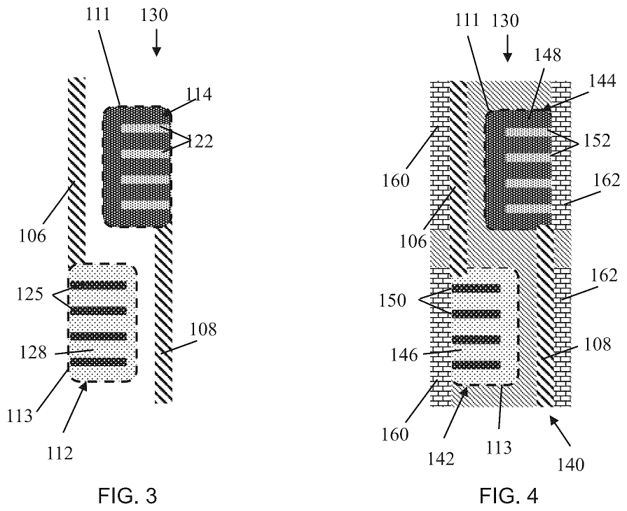

Referring to FIG. 3, channels 122 and 125 are shown partially overlapping when viewed along direction 130 for a tri-gate transistors. In this embodiment, the channels 125 are also longer than channels 122. It should be understood that channels can be different lengths relative to one another. Even if the channels 122 and 125 are of the same length the channels 122 and 125 can partially overlap or not overlap at all. Opposite connections can be made directly by contacts 106, 108 to S/D regions 113, 111, respectively. As such, an effective cell width does not include lateral extensions for landing the contacts 106, 108. Such lateral extensions would add width to the cell.

Referring to FIG. 4, a cell 140 includes tri-gate transistors 142 and 144 in accordance with another embodiment. A top tier transistor 144 includes a gate 148 and channels 152 that form channels between a source region and a drain region (a projection of a source/drain region 111 is shown in dotted lines) above and below the plane of the page. A bottom tier transistor 142 includes a gate 146 and channels 150 that form channels between a source region and a drain region (a projection of a source/drain region 113 is shown in dotted lines) above and below the plane of the page. In accordance with one embodiment, the channels 152 of the top tier transistor 154 are located on a first edge, and the channels 150 of the bottom tier transistor 142 are located on a second edge on an opposite side relative to the first edge. Here, the channels 150 and 152 contact dielectric spines 160 and 162 respectively. The dielectric spines 160 and 162 provide dielectric insulation on one side of the channels 150, 152. The channels 150 and 152 can partially overlap with each other or not overlap with each other at all. The size of the channels 150 and 152 can be the same or different.

The cell 140 includes a contact 106 that extends from a front side or top tier to make an opposite connection and directly contacts a bottom tier S/D region 113. A contact 108 extends from a backside or bottom tier to make an opposite connection and directly contact a top tier S/D region 111. Since opposite connections can be made directly by contacts 106, 108, an effective cell width does not include lateral extensions for landing the contacts 106, 108. Such lateral extensions would add width to the cell.

It should be understood that while two contacts 106 and 108 are depicted in FIGS. 1-4, the present embodiments could employ a single connection contact and still benefit from the advantages described herein.

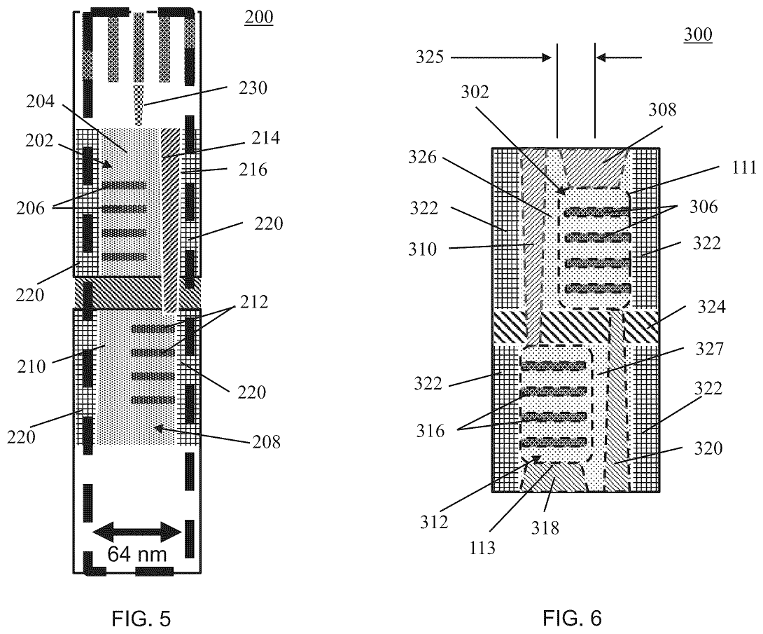

Referring to FIG. 5, a cell 200 is illustratively depicted as a 4 transistor (4T) inverter complementary lever (c-lever) cell with an exemplary cell height of 64 nm that employs tri-gate transistors. A top tier transistor 202 includes a gate 204 and channels 206 that form a selective conductive path between a source region and a drain region (not shown) above and below the plane of the page. A bottom tier transistor 208 includes a gate 210 and channels 212 that form channels between a source region and a drain region (not shown) above and below the plane of the page. In accordance with one embodiment, the channels 206 of the top tier transistor 202 are located toward a left edge of FIG. 5, and the channels 212 of the bottom tier transistor 208 are located toward a right edge of FIG. 5. Here, the channels 206 and 212 abut dielectric spines 220 on one side. The dielectric spines 220 provide dielectric insulation on one side of the channels 206, 212. The channels 206 and 212 can partially overlap each other or not overlap each other at all. The size of the channels 206 and 212 can be the same or different.

The cell 200 includes a gate contact 214 that extends from a front side to make an opposite connection and directly contact the gate 210. The contact 214 passes the gate 204. In some embodiments, gate contact 214 can be connected to gate 204. In other embodiments, gate contact 214 can be electrically isolated from the gate 204 by a dielectric barrier 216 around the contact 214. Since an opposite connection can be made directly by contact 214 to gates 210, an effective cell width is reduced.

Referring to FIG. 6, a cell 300 employs tri-gate transistors having multiple contact connections. A top tier transistor 302 includes a gate 326 and channels 306 that form channels between a source region and a drain region above and below the plane of the page. A bottom tier transistor 312 includes a gate 327 and channels 316 that form channels between a source region and a drain region above and below the plane of the page. In accordance with one embodiment, the channels 306 of the top tier transistor 302 are located on a right edge and abut a dielectric spine 322. The channels 316 of the bottom tier transistor 312 are located on a left edge (opposite the right edge) and abut a dielectric spine 322. The dielectric spines 322 provide dielectric insulation on one side of the channels 306, 316.

Here, the S/D drain region 111 (dotted line) of the top tier transistor 302 is contacted from a top side by contact 308 and a backside by contact 320. Similarly, the S/D drain region 111 (dotted line) of the bottom tier transistor 312 is contacted from a bottom side by contact 318 and a topside by contact 310. A dielectric material 324 separates the top tier transistor 302 from the bottom tier transistor 312. Contacts 308, 310, 318 and 320 are to S/D regions 111, 113 and are depicted with dotted lines. Contacts 308, 310, 318 and 320 do not contact the gates 326 and 327 as the contacts are S/D contacts and depicted in projections to show the relationships with the gate and channels.

The channels 306 and 316 are partially overlapped, but embodiments where a greater overlap or no overlap is present are also contemplated. The size of the channels 306 and 316 can be the same or different. In this embodiment, the S/D regions 111, 113 are partially overlapped by a distance 325. Since, as before, an opposite connection can be made directly by contacts 310 and 320 to S/D regions, an effective cell width is reduced since no additional lateral conductive structures are needed to land these contacts.

S/D regions 111, 113 can be connected by the opposite contacts but also from a “same side” contact. For example, if power or ground is delivered from the backside of the device, a bottom FET S/D region is contacted to power or ground by a contact from the backside, and the top FET is contacted to power or ground by the opposite contact from the backside. If the signal lines are on the frontside of the device, the top FET S/D region is connected to signal by a contact from the frontside and the bottom FET S/D region is connected by the opposite contact from the frontside. It should be understood that a given S/D region (e.g., S/D region 111, 113 or corresponding S/D regions (not shown) on the other side of the gates 326, 327 could have one contact, no contact or two contacts (one from top and one from the bottom).

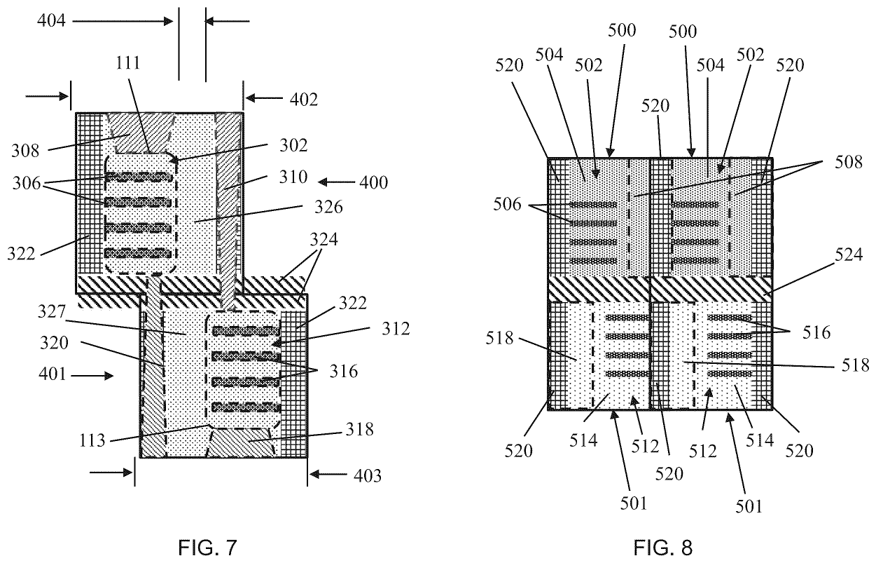

Referring to FIG. 7, staggered cells 400 and 401 employ tri-gate transistors having multiple possible contact connections. S/D regions and channels are staggered and can overlap or not overlap. In accordance with one embodiment, the channels 306 of the top tier transistor 302 are located on a left edge and abut a dielectric spine 322. The channels 316 of the bottom tier transistor 312 are located on a right edge and abut a dielectric spine 322. The dielectric spines 322 provide dielectric insulation on one side of the channels 306, 316.

In one embodiment, a cell height 402 for cell 400 is shifted from a cell height 403 of cell 401. In this way a staggered pattern is created with transistors 302, 312 offset with no overlap to form a spacing 404 therebetween. Cells 400 and 401 can be identical but reoriented. In other embodiments, the cells 400 and 401 can be different. In still other embodiments, the structures within each cell 400, 401 can be different. For example, the transistors and the channels can have different shapes and sizes but provide a staggered pattern to enable opposite connections.

As shown in FIG. 7, the dotted S/D region of the top tier transistor 302 is contacted from a top side by contact 308 and/or a backside by contact 320. Similarly, the dotted S/D region of the bottom tier transistor 312 is contacted from a bottom side by contact 318 and/or a topside by contact 310. Dielectric material 324 separates the top tier transistor 302 from the bottom tier transistor 312.

The channels 306 and 316 do not overlap with one another. The size of the channels 306 and 316 can be the same or different (e.g., different lengths). Due to the staggered pattern, the contacts 310 and 320 are further away from S/D regions 111, 113 within each cell. With the staggered cells 400 and 401, improvement in the effective width for the cells can be realized. Opposite connections can be enabled without the need for additional lateral conductive structures to land the contacts 310 and 320. It should be understood that a given S/D region (e.g., S/D region 111, 113 or corresponding S/D regions (not shown) on the other side of the gates 326, 327 could have one contact, no contact or two contacts (one from top and one from the bottom).

Many configurations can be realized that provide improved effective cell width and enable opposite connections in accordance with embodiments of the present invention. Individual cells can include shifted gates, shifted channels, shifted transistors between top and bottom layers to permit opposite connections for stacked transistor devices. Further, cells (including transistors with gates, channels etc.) can be shifted or staggered between top and bottom tiers to permit opposite connections for stacked transistor devices. In some embodiment, the dielectric spines can align with dielectric spines in other layers (e.g., top tier versus bottom tier) within a cell column. In other embodiments, the dielectric spines can align with gate cuts in other layers (e.g., top tier versus bottom tier) (e.g., top tier versus bottom tier) that can include non-dielectric materials or can include contacts within the gate cut. In still other embodiments, the dielectric spines and/or gate cuts can be misaligned between tiers.

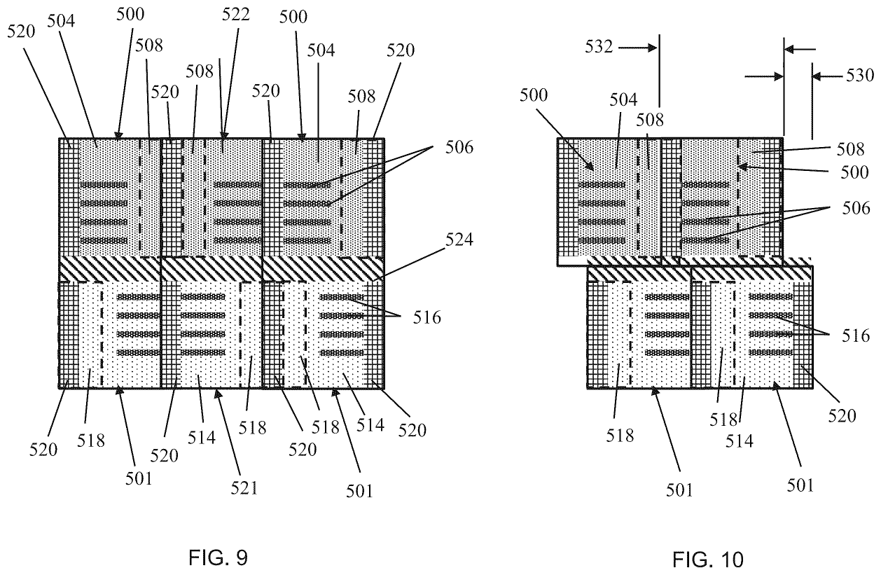

Referring to FIG. 8, cells 500 are placed adjacent to one another and over cells 501. Cells 500 and 501 employ tri-gate transistors with channels 506 and 516 on opposing sides of a cell stack formed by cells 500 and 501. Each cell 500 includes a top tier transistor 502, includes a gate 504 and includes channels 506 that form channels between a source region and a drain region (not shown) above and below the plane of the page. Each cell 501 includes a bottom tier transistor 512, includes a gate 514 and includes channels 516 that form channels between a source region and a drain region (not shown) above and below the plane of the page. In accordance with one embodiment, the channels 506 of the top tier transistor 502 are located on a left edge and abut a dielectric spine 520. The channels 516 of the bottom tier transistor 512 are located on a right edge and abut a dielectric spine 520. The dielectric spines 520 provide dielectric insulation of one side of the channels 506, 516. The pattern and orientation of cells 500 and cells 501 can be maintained throughout an architecture of a semiconductor device. This pattern can be referred to as a back-to-front (or front-to-back) pattern at each tier (e.g., a top level or a bottom level). Other patterns are also contemplated (see e.g., FIG. 9). A dielectric material 524 separates the top tier transistors 502 from the bottom tier transistors 512.

The channels 506 and 516 are partially overlapped, but embodiments where no overlap is present are also contemplated. The size of the channels 506 and 516 can be the same or different. In this embodiment, the gates 504 and 514 are partially overlapped between top cells 500 and bottom cells 501. In other embodiments, the gates 504 and 514 can include no overlap. It should be understood that cells 500 and 501 can be combined to form a single cell.

Gate cut regions 508 and 518 can be enlarged (as indicated by dotted lines) as a result of the component shifts in accordance with embodiments of the present invention. Gate cut regions 508 and 518 include dielectric material. In other embodiments, the channels 506 and 516 and gates 504 and 514 can be shifted in the other direction from the one depicted in FIG. 8. Opposite connections can be made directly by contacts to S/D regions to reduce an effective cell width by eliminating the need for additional conductive structures to land the contacts.

Referring to FIG. 9, cells 500 and 522 can be alternated for a top tier of a device, and cells 501 and 521 can be alternated for a bottom tier of the device. In this pattern, the cells 500 and 522 of a top tier include channels 506 on opposite sides of a same dielectric spine 520 that correspond with cells 501 and 521 on a bottom tier which include channels 516 that are spaced apart from the top tier. This pattern can be referred to as a back-to-back pattern that alternates between the top tier and bottom tier. Gate cut regions 508 and 518 (indicated by dotted lines) can be enlarged as a result of the component shifts in accordance with embodiments of the present invention. Gate cut regions 508 and 518 include dielectric material. A dielectric material 524 separates cells 500 from cells 501.

The channels 506, 516 partially overlap between top cells 500, 522 and their corresponding bottom cells 501, 521, but embodiments where no overlap is present are also contemplated. The sizes of the channels 506 and 516 and/or gates 504 and 514 can be the same or different between tiers. In this embodiment, the gates are partially overlapped between top cells 500, 522 and bottom cells 501, 521. In other embodiments, the gates can include no overlap.

It should also be understood that the channels 506 and 516 and gates 504 and 514 can be shifted in the other direction from the directions depicted in FIG. 9. Opposite connections can be made directly by contacts to S/D regions to reduce an effective cell width by eliminating the need for additional conductive structures to land the contacts.

Referring to FIG. 10, cells 500 and cells 501 are arranged in a staggered cell configuration in accordance with another embodiment. Cells 500 and 501 can be offset 530 anywhere between greater than 0% to up to 50% of a cell height 532. Cells 500 and 501 are staggered to realize effective width improvements. The channels 506 and 516 are partially overlapped between top cells 500 and their corresponding bottom cells 501, but on an edge corresponding to the dielectric spine 520. Embodiments where no overlap is present are also contemplated. The sizes of the channels 506 and 516 and gates 504 and 514 can be the same or different. In this embodiment, the gates 504 and 514 are partially overlapped on both sides of the gate between top cell 500 and bottom cell 501. In other embodiments, the gates 504 and 514 can include no overlap. It should also be understood that the channels 506 and 516 and gates 504 and 514 can be shifted in the other direction from the directions depicted in FIG. 10. Opposite connections can be made directly by contacts to S/D regions to reduce an effective cell width by staggering the cells and eliminating the need for additional conductive structures to land the contacts.

Gate cut regions 508 and 518 (indicated by dotted lines) can be enlarged as a result of the component shifts in accordance with embodiments of the present invention. Gate cut regions 508 and 518 include dielectric material.

In accordance with the present embodiments, stacked transistors described herein can include any type of device. In one embodiment, the transistor types include field effect transistors (FETs) and in particular tri-gate (e.g., forksheet) field effect transistors. The top tier device and the bottom tier device can include different conductivities. N-type FETs (NFETs), P-type FETs (PFETs) can be employed for the top and bottom device, in any combination, e.g., top/bottom can be NFET/PFET (or N/P), P/N, N/N, P/P. In some embodiments, top or bottom rows of devices can alternate between P/N or be all N or all P.

FIGS. 1-10 have depicted top and bottom tier FET structures with gate widths being about the same; however, in some embodiments, the gates can be aligned over each other or staggered by a length equal to or lower than the gate width. The gates can have different widths. The different gate widths can be aligned by a gate edge of the top FET and a gate edge of the bottom FETs. The gates for the top and bottom FETs can overlap, be staggered with no overlap or be staggered but have an overlapped portion in the horizontal direction between gates. The dielectric spines or gate cuts can be present on at least one side of a cell. The dielectric spines or gate cuts can be enlarged to regions 508, 518 (as depicted by dotted lines in FIGS. 8-10). The gate cuts can be asymmetric in length (depth). The gate cuts can have different widths, e.g., the gate cut in contact with the channels can be wider than the gate cut not in contact with the channels (see e.g., FIG. 9). In some embodiments, gate cuts of the top tier FETs can be wider that gate cuts for the bottom tier FETs.

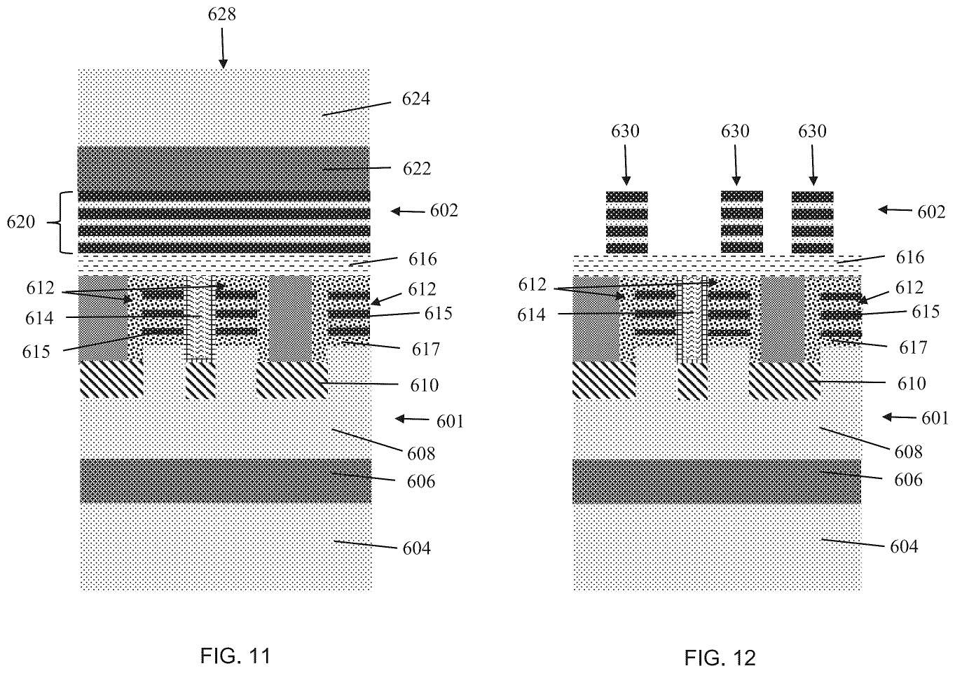

Referring to FIG. 11, a cross-sectional view of an illustrative tri-gate transistor structure is shown in accordance with embodiments of the present invention. Tri-gate transistors can be part of a stacked field effect transistor (FET) device in accordance with embodiments of the present invention. In the embodiment shown, a first tier 601 is processed to form tri-gate transistors on a substrate 604. The substrate 604 can include any suitable substrate structure, e.g., a bulk semiconductor, a semiconductor-on-insulator (SOI) substrate, etc., and preferably includes a monocrystalline semiconductor. The substrate 604 can include an etch stop layer 606 and a semiconductor portion 608.

The semiconductor portion 608 is etched and filled with dielectric material to form shallow trench isolation (STI) 610. Gates 612 are formed, e.g., by employing nanosheets, which form channels 615, which are encapsulated by a gate conductor 617 on three sides. A dielectric spine or gate cut 614 contacts the channels 615 on one side. The gate cut 614 can include one or more dielectric materials, e.g., a dielectric liner and a dielectric fill. The dielectric spine or gate cut 614 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, a-C: H). The dielectric spine or gate cut 614 can be deposited using chemical vapor deposition (CVD), although other deposition methods can be employed.

An interface layer 616 is disposed on the bottom tier 601 for the addition of a top tier 602 thereon. The top tier 602 includes a wafer 628, which can be transferred by a wafer transfer process and be bonded to the interface layer 616. The wafer 628 can include any suitable structure. In accordance with one embodiment, the wafer 628 includes, e.g., a bulk semiconductor portion 624, an etch stop layer 622 and one or more nanosheets 620 of alternating semiconductor materials (e.g., Si and SiGe).

Referring to FIG. 12, the bulk semiconductor portion 624 and etch stop layer 622 can be removed and the nanosheet 620 can be patterned. The nanosheet 620 is patterned to form stacks 630 for the formation of future channels for the top tier 602. The stacks 630 are placed in positions relative to gates 612 in the bottom tier 601 such that the positions of the stacks 630 enable contact access and reduce overall device width as described in accordance with the embodiments of the present invention.

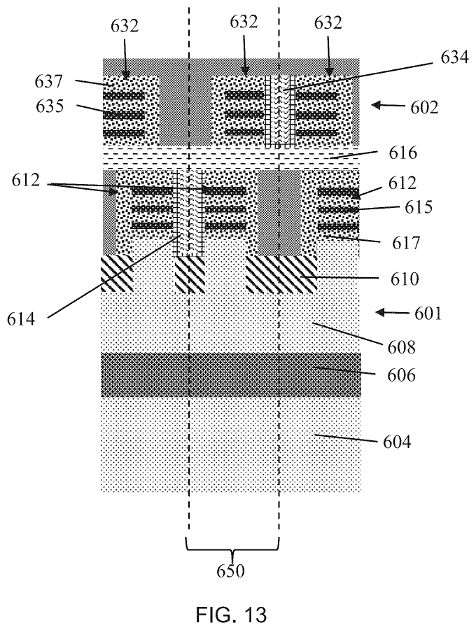

Referring to FIG. 13, trigate transistors for the top tier 602 are completed. Gates 632 including channels 635 encapsulated by a gate conductor 637 on three sides are formed. A dielectric spine or gate cut 634 contacts the channels 635 on one side. The dielectric spine or gate cut 634 can include one or more dielectric materials, e.g., a dielectric liner and a dielectric fill. The dielectric spine or gate cut 634 can include any suitable material.

S/D regions (not shown) corresponding to gates 632 and 612 are placed in positions relative to each other such that contact access is provided and an overall reduction in device width is achieved. The gates 632 and corresponding S/D regions with shifted channels within a given column 650 are offset from the gates 612 and corresponding S/D regions in the column 650 as between the top tier 602 and the bottom tier 601 in accordance with the embodiments of the present invention.

Other contacts have been omitted from FIGS. 11-13 for clarity; however, contacts can be formed to make connections with source/drain regions and gates as described herein. This can include the formation of opposite connections. Contacts for opposite connections and other contacts can include a silicide liner, such as Ti, Ni, NiPt and/or a diffusion barrier formed in the opening for the contact prior to fill. The diffusion barrier can include, e.g., TiN, TaN, or similar materials. A conductive fill is performed to form the contacts for opposite connections, gate contacts or any other contacts and can include materials, such as, e.g., Cu, Ru, Mo, Rh, W, Ir, and alloys or combinations of these and other conductive materials.

It should be understood that S/D regions, gates and channels depicted in FIGS. 11-13 are offset to enable favorable contact placement and decrease cell height (column width) in accordance with embodiments of the present invention. As noted above, the S/D regions correspond with the width of the channels within the column 650 except are located proximally to the page or distally into the page.

Processing can continue with the formation of additional tiers or with back end of the line (BEOL) layers on the top tier of the device. Contacts including opposite connection contacts can be formed on both sides of the device.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising:
a stacked transistor structure including a column having field effect transistors on at least two levels in the column, the at least two levels including a top tier and bottom tier; and
first channels of a first field effect transistor disposed on a first side of the column at the top tier and second channels of a second field effect transistor disposed on a second side of the column opposite the first side at the bottom tier to form an offset between the first channels and the second channels within the column.

2. The semiconductor device of claim 1, wherein the first channels abut a dielectric spine of the first side and the second channels about a dielectric spine on the second side.

3. The semiconductor device of claim 1, wherein the first channels and the second channels have different sizes.

4. The semiconductor device of claim 1, wherein the first field effect transistor includes a source/drain region which is offset from a source/drain region of the second field effect transistor within the column.

5. The semiconductor device of claim 4, further comprising at least one opposite connection contact disposed within the column and through one of the at least two levels to connect to a source/drain region in another one of the at least two levels.

6. The semiconductor device of claim 5, wherein the at least one opposite connection includes two opposite connections within the column.

7. The semiconductor device of claim 1, wherein the first field effect transistor includes a tri-gate field effect transistor.

8. The semiconductor device of claim 1, wherein the offset provides overlap between the first channels and the second channels within their respective levels of the at least two levels in the column.

9. The semiconductor device of claim 1, wherein the offset is large enough to prevent overlap between the first channels and the second channels within their respective levels of the at least two levels in the column.

10. The semiconductor device of claim 1, wherein the column is defined in accordance with a cell height and the offset includes a staggered pattern between the first channels and the second channels within their respective levels of the at least two levels in the column.

11. The semiconductor device of claim 1, further comprising a dielectric spine aligned through the top tier and the bottom tier within the column.

12. A semiconductor device comprising:
a stacked transistor structure including a column having tri-gate field effect transistors on at least two levels in the column, the at least two levels including a top tier and bottom tier;
a first tri-gate field effect transistor disposed on a first side of the column at the top tier and a second tri-gate field effect transistor offset from the first tri-gate field effect transistor on a second side of the column opposite the first side at the bottom tier within the column; and
at least one opposite connection contact disposed within the column, the at least one opposite connection passing through the column to connect to one of the first and second tri-gate transistors.

13. The semiconductor device of claim 12, wherein the first tri-gate field effect transistor and the second tri-gate field effect transistor each include gates with gate conductors that surround three sides of device channels.

14. The semiconductor device of claim 13, wherein the gates have different sizes.

15. The semiconductor device of claim 13, wherein the device channels of the first tri-gate field effect transistor and the second tri-gate field effect transistor have different sizes.

16. The semiconductor device of claim 15, wherein the device channels of the first tri-gate field effect transistor and the second tri-gate field effect transistor abut dielectric spines on opposite sides of the column.

17. The semiconductor device of claim 15, wherein the device channels for adjacent tri-gate field effect transistors in a same layer of the at least two levels abut a same dielectric spine.

18. The semiconductor device of claim 12, wherein the at least one opposite connection includes two opposite connections within the column.

19. The semiconductor device of claim 12, wherein the at least one opposite connection connects to a source drain region of one of the first and second tri-gate transistors.

20. A semiconductor device comprising:
a stacked transistor structure including a column having tri-gate field effect transistors on at least two levels in the column, the at least two levels including a top tier and bottom tier; and
a first tri-gate field effect transistor having channels disposed on a first side of the column at the top tier and a second tri-gate field effect transistor having channels disposed on a second side of the column opposite the first side at the bottom tier to form an offset between the channels of first tri-gate field effect transistor and the channels of the second tri-gate field effect transistor within the column, wherein the offset provides overlap between the channels of the first tri-gate field effect transistor and the channels of the second tri-gate field effect transistor within their respective levels of the at least two levels in the column.
